(19) United States
(12) Patent Application Publication
(10) Pub. No.: US 2011/0186916 A1
(43) Pub. Date: Aug. 4, 2011

(54) SEMICONDUCTOR RESISTORS FORMED IN A SEMICONDUCTOR DEVICE COMPRISING METAL GATES BY REDUCING CONDUCTIVITY OF A METAL-CONTAINING CAP MATERIAL

(76) Inventors: Andreas Kurz, Dresden (DE); Christoph Schwan, Dresden (DE)

(21) Appl. No.: 12/917,599

(22) Filed: Nov. 2, 2010

(30) Foreign Application Priority Data
Jan. 29, 2010 (DE) 10 2010 001 397.8

(51) Int. Cl. H01L 27/06; H01L 21/02

(52) U.S. Cl. 257/288; 438/382; 257/E27.016; 257/E21.004

(57) ABSTRACT

In semiconductor devices comprising sophisticated high-k metal gate electrode structures, resistors may be formed on the basis of a semiconductor material by increasing the sheet resistance of a conductive metal-containing cap material on the basis of an implantation process. Consequently, any complex etch techniques for removing the conductive cap material may be avoided.

### BACKGROUND OF THE INVENTION

1. Field of the Invention

The present disclosure generally relates to the field of fabricating integrated circuits, and, more particularly, to resistors in complex integrated circuits that comprise metal gate electrode structures.

2. Description of the Related Art

In modern integrated circuits, a very high number of individual circuit elements, such as field effect transistors in the form of CMOS, NMOS, PMOS elements, are formed on a single chip area. Typically, feature sizes of these circuit elements are steadily decreasing with the introduction of every new circuit generation, to provide currently available integrated circuits with a high performance in terms of speed and/or power consumption. A reduction in size of transistors is an important aspect in steadily improving device performance of complex integrated circuits, such as CPUs. The reduction in size commonly brings about an increased switching speed, thereby enhancing signal processing performance.

In addition to the large number of transistor elements, a plurality of passive circuit elements, such as capacitors and resistors, are typically formed in integrated circuits as required by the basic circuit layout. Due to the decreased dimensions of circuit elements, not only the performance of the individual transistor elements may be improved, but also their packing density may be significantly increased, thereby providing the potential for incorporating increased functionality into a given chip area. For this reason, highly complex circuits have been developed, which may include different types of circuits, such as analog circuits, digital circuits and the like, thereby providing entire systems on a single chip (SOC).

Although transistor elements are the dominant circuit element in highly complex integrated circuits and substantially determine the overall performance of these devices, the passive components, such as the resistors, may also strongly influence the overall device performance, wherein the size of these passive circuit elements may also have to be adjusted with respect to the scaling of the transistor elements in order to not unduly consume valuable chip area. Moreover, the passive circuit elements, such as the resistors, may have to be provided with a high degree of accuracy in order to meet tightly set margins according to the basic circuit design. For example, even in substantially digital circuit designs, corresponding resistance values may have to be provided within tightly set tolerance ranges so as to not unduly contribute to operational instabilities and/or increased signal propagation delay. For example, in sophisticated applications, resistors may frequently be provided in the form of “integrated polysilicon” resistors which may be formed above isolation structures so as to obtain the desired resistance value without significantly contributing to parasitic capacitance, as may be the case in “buried” resistive structures which may be formed within the active semiconductor layer. A typical polysilicon resistor may thus require the deposition of the basic polysilicon material, which may frequently be combined with the deposition of a polysilicon gate electrode material for the transistor elements. During the patterning of the gate electrode structures, the resistors may also be formed, the size of which may significantly depend on the basic specific resistance value of the polysilicon material and the subsequent type of dopant material and concentration that may be incorporated into the resistors so as to adjust the resistance values. Since, typically, the resistance value of doped polysilicon material may be a non-linear function of the dopant concentration, specific implantation processes are typically required, independent of any other implantation sequences for adjusting the characteristics of the polysilicon material of the gate electrodes of the transistors.

Moreover, the continuous drive to shrink the feature sizes of complex integrated circuits has resulted in a gate length of field effect transistors of approximately 50 nm and less. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, referred to as a channel region, that is disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon forming a conductive channel due to the application of an appropriate control voltage to the gate electrode, depends on the dopant concentration of the drain and source regions, the mobility of the charge carriers and, for a given transistor width, on the distance between the source region and the drain region, which is also referred to as channel length.

Presently, most complex integrated circuits are based on silicon due to the substantially unlimited availability, the well-understood characteristics of silicon and related materials and processes and due to the experience gathered during the last 50 years. Therefore, silicon will likely remain the material of choice for future circuit generations. One reason for the important role of silicon for the fabrication of semiconductor devices has been the superior characteristics of a silicon/silicon dioxide interface that allows a reliable electrical insulation of different regions from each other. The silicon/silicon dioxide interface is stable at high temperatures and, thus, allows high temperature processes to be performed, as are typically required for anneal processes in order to activate dopants and to cure crystal damage without sacrificing the electrical characteristics of the interface. Consequently, in field effect transistors, silicon dioxide has been preferably used as a base material for gate insulation layers which separate the gate electrode, frequently comprised of polysilicon, from the silicon channel region. Upon the further device scaling, however, the reduction of the channel length may require a corresponding adaptation of the thickness of the silicon dioxide based gate dielectric in order to substantially avoid a so-called short channel behavior, according to which a variability in channel length may have a significant influence on the resulting threshold voltage of the transistor. Aggressively scaled transistor devices with a relatively low supply voltage and, thus, a reduced threshold voltage, therefore, suffer from a significant increase of the leakage current caused by the reduced thickness of a silicon dioxide gate dielectric.

For this reason, replacing silicon dioxide as the material for gate insulation layers has been considered, particularly for highly sophisticated applications. Possible alternative materials include such materials that exhibit a significantly higher permittivity, so that a physically greater thickness of a correspondingly formed gate insulation layer provides a capacitive coupling that would be obtained by an extremely thin silicon dioxide layer. It has thus been suggested to replace silicon dioxide with high permittivity materials, such as tantalum oxide, strontium titanium oxide, hafnium oxide, hafnium silicon oxide, zirconium oxide and the like.

Additionally, transistor performance may further be increased by providing an appropriate conductive material for the gate electrode in order to replace the usually used polysilicon material, since polysilicon may suffer from charge carrier depletion at the vicinity of the interface positioned between the gate dielectric material and the polysilicon material, thereby reducing the effective capacitance between the channel region and the gate electrode during transistor operation. Thus, a gate stack has been suggested in which a high-k dielectric material provides enhanced capacitance, while additionally maintaining any leakage currents at an acceptable level. Since the non-polysilicon material, such as titanium nitride and the like, may be formed such that it may be directly in contact with gate dielectric material, the presence of a depletion zone may thus be avoided, while, at the same time, a moderately high conductivity is achieved.

As is well known, the threshold voltage of the transistor may depend on the overall transistor configuration, on a complex lateral and vertical dopant profile of the drain and source regions and the corresponding configuration of the PN junctions and on the work function of the gate electrode material. Consequently, in addition to providing the desired dopant profiles, the work function of the metal-containing gate electrode material also has to be appropriately adjusted with respect to the conductivity type of the transistor under consideration. For this reason, typically, metal-containing electrode materials may be used for N-channel transistors and P-channel transistors, which may be provided according to well-established manufacturing strategies in a very advanced manufacturing stage. In some of these so-called replacement gate approaches, the high-k dielectric material may be formed in combination with an appropriate metal-containing cap layer, such as titanium nitride and the like, followed by the deposition of a polysilicon material in combination with other materials, if required, which may then be patterned in order to form a gate electrode structure. Concurrently, corresponding resistors may be patterned, as described above. Thereafter, the basic transistor configuration may be completed by forming drain and source regions, performing anneal processes and finally embedding the transistors in a dielectric material. Thereafter, an appropriate etch sequence is performed in which the top surfaces of the gate electrode structures, and all resistive structures, are exposed and the polysilicon material is removed. Subsequently, based on a respective masking regime, appropriate metal-containing electrode materials are filled into gate electrode structures of N-channel transistors and P-channel transistors, respectively, in order to obtain a superior gate structure, including a high-k gate insulating material in combination with a metal-containing electrode material, which may provide an appropriate work function for N-channel transistors and P-channel transistors, respectively. Concurrently, the resistive structures also receive the metal-containing electrode material. Due to the enhanced conductivity of the metal-containing electrode material, however, the resistivity of the resistive structures may also exhibit a significantly reduced value, thereby requiring a reduction of line widths of these structures and/or an increase of the total length of these structures. While the former measure may result in patterning problems, since extremely small line widths may be required, the latter aspect may result in an increased consumption of variable chip area.

Consequently, in these replacement gate approaches, it has been proposed to remove the polysilicon material selectively from the metal gate electrodes structures only, while preserving the polysilicon material in the non-FET circuit elements, such as the resistors. To this end, additional complex process steps may be applied, wherein, however, nevertheless, the moderately low sheet resistance of the metal-containing cap material may result in an overall reduced resistivity of the resistive structures, which may thus result in significant design efforts so as to reconfigure corresponding polysilicon resistors to obtain the desired resistance values. In particular, for high precision polysilicon resistors, significant additional process steps may have to be implemented into the overall process flow.

Similarly, in other metal gate approaches, in which the gate electrode structures are completed in an early manufacturing stage, i.e., by providing the high-k dielectric material in combination with a metal-containing cap material and appropriate work function adjusting metal species, the high-k dielectric material and the metal-containing cap material may still be present in the resistive structures, which may, thus, also result in a superior conductivity, which may of course be desirable for the metal gate electrode structures, which, however, requires significant redesigns of the resistive structures. In other conventional approaches, the metal-containing cap material may be selectively removed from the resistive structures, which, however, requires additional etch processes in an early manufacturing stage, which may have a significant influence on other device areas, thereby contributing to additional complexity of the per se very complex sophisticated manufacturing sequence for providing the metal gate electrode structures including a metal-containing cap material and the polysilicon material in an early manufacturing stage.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which semiconductor-based resistive structures may be provided in semiconductor devices having formed thereon high-k metal gate electrode structures, which may be accomplished by selectively increasing the sheet resistance of the metal-containing cap material in the presence of the semiconductor material. To this end, an implantation process may be applied so as to implant a heavy atomic species into and near the metal-containing cap material, thereby creating significant damage in the conductive layer, which may thus result in an interruption of the continuous conductive layer, thereby significantly increasing the sheet resistance. The selective increasing of the sheet resistance may be implemented at any appropriate stage of the overall manufacturing process, for instance when adjusting the specific resistivity of the semiconductor material in the resistive structures on the basis of an implantation process, thereby enabling using one and the same implantation mask. The principles disclosed herein may be advantageously applied to process techniques in which high-k metal gate electrode structures may be provided in an early manufacturing stage, i.e., the high-k dielectric material in combination with a work function adjusting metal species and a conductive metal-containing cap material are provided together with a semiconductor electrode material, so that any complex masking and etch processes for removing at least the metal-containing cap material in the resistor structures may be avoided, thereby resulting in an efficient manufacturing flow compared to conventional strategies. In other cases, the principles disclosed herein may also be applied to replacement gate approaches, wherein the removal of the semiconductor material may be restricted to the high-k metal gate electrode structures, while the undesired high conductivity of a metal-containing cap material in the preserved resistor structures may be efficiently reduced.

One illustrative semiconductor device disclosed herein comprises a transistor comprising a gate electrode structure, which comprises a high-k gate dielectric material and a metal-containing electrode material formed above the high-k dielectric material. The semiconductor device further comprises a resistor comprising a semiconductor material formed above a material layer that comprises species of the high-k dielectric material and of the metal-containing electrode material. The material layer has a sheet resistance that is higher than a sheet resistance of the metal-containing electrode material of the gate electrode structure.

One illustrative method disclosed herein relates to forming a resistive structure of a semiconductor device. The method comprises forming a gate electrode structure of a transistor above a first device region and forming a resistor structure above a second device region of the semiconductor device. The gate electrode structure and the resistor structure comprise a high-k dielectric material, a metal-containing cap layer and a semiconductor material. The method further comprises increasing a sheet resistance of the metal-containing cap layer selectively in the resistor structure.

A further illustrative method disclosed herein comprises forming a resistive structure above an isolation structure of a semiconductor device, wherein the resistive structure comprises a semiconductor material that is formed above a high-k dielectric material and a metal-containing cap layer. The method further comprises increasing a sheet resistance of the metal-containing cap layer by implanting a heavy species into the metal-containing cap layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1f schematically illustrate cross-sectional views of a semiconductor device during various manufacturing stages in forming a resistive structure and a transistor by using a high-k dielectric material and a metal-containing cap layer in combination with a semiconductor electrode material, wherein the sheet resistance of the metal-containing cap material is increased, according to illustrative embodiments; and

FIGS. 1g-1k schematically illustrate cross-sectional views of the semiconductor device during various manufacturing stages, in which gate electrode structures are formed on the basis of a replacement gate approach, while the resistive structures are formed on the basis of a semiconductor material in combination with a metal-containing cap material having an increased sheet resistance, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and manufacturing techniques in which non-FET devices may be formed on the basis of a semiconductor material, such as polysilicon, polysilicon/germanium and the like, while the gate electrode structures of field effect transistors may be formed on the basis of a high-k dielectric material in combination with a metal-containing electrode material, wherein, in some embodiments, the semiconductor material may also be preserved as an electrode material in the gate electrode structures. To this end, the sheet resistance of the metal-containing cap material may be significantly increased selectively in device regions, in which the resistor structures or any other non-FET elements are to be formed. In some illustrative embodiments, increasing the sheet resistance may be performed after patterning the gate electrode structures and the resistor structures, for instance prior to performing any high temperature processes, thereby enabling the implantation of a heavy implantation species, such as xenon, which may thus significantly modify the structure of the metal-containing cap material. Consequently, the continuous metal-containing cap layer may be electrically interrupted so that a continuous conductive layer may no longer be present below the semiconductor material, so that the overall resistivity of the resistive structure is substantially determined by the semiconductor material rather than the per se moderately highly conductive metal-containing cap material. On the other hand, the superior conductivity of the metal-containing cap material, which may also be referred to as a metal-containing electrode material, results in superior electrical performance in the high-k metal gate electrode structures. Thereafter, if desired, any high temperature processes may be performed, for instance for activating dopants and the like, thereby also forming a polycrystalline semiconductor material in gate electrode structures and in the resistive structure. Thus, the resistance value of the resistive structure may be adjusted with high precision on the basis of well-established and well-known material characteristics and dopant profiles of conventional semiconductor-based resistors.

Consequently in approaches in which gate electrode structures are to be provided in an early manufacturing stage, i.e., the work function adjustment may be accomplished prior to or upon patterning the gate electrode structures and well-established semiconductor materials, such as silicon, may still act as a part of the electrode material, in combination with the metal-containing cap layer, the resistive structures may be provided on the basis of well-established design concepts and materials, since the specific resistivity of the resistor material is substantially determined by the characteristics of the semiconductor material. In some illustrative embodiments, a reconfiguration of part of the previously interrupted metal-containing cap layer may be efficiently prevented by incorporating an additional diffusion hindering species, such as carbon and the like, thereby suppressing or efficiently reducing the diffusion of any species of the metal-containing cap layer during the further processing, for instance when performing high temperature anneal processes. For example, one and the same implantation mask may be used for incorporating the heavy species for increasing the sheet resistance of the metal-containing cap material and for incorporating the diffusing reducing species. Furthermore, in other embodiments, additionally, an implantation step may be performed so as to incorporate additional dopant species selectively into the semiconductor material of the resistive structure in order to appropriately adjust the specific resistivity of the semiconductor material. The corresponding implantation process may also be performed by using the previously used implantation mask, thereby contributing to a very efficient overall process flow.

In other cases, the implantation process for increasing the sheet resistance may be performed at any appropriate manufacturing stage, while any further implantation steps may be applied as required.

The selective increasing of the sheet resistance of a metal-containing cap material may also be efficiently applied in replacement gate approaches, wherein the replacement of the semiconductor material in a late manufacturing stage may be selectively prevented in the resistor structures. Moreover, the increased conductivity of the conductive cap material, which may be provided in an early manufacturing stage together with a high-k dielectric material, may be efficiently reduced on the basis of an ion implantation process, as discussed above. Moreover, in some illustrative embodiments, the etch resistivity of the semiconductor material in the resistive structures may be selectively increased by incorporating an appropriate species, such as xenon, which may be accomplished, if desired, by using the same implantation mask as used for increasing the sheet resistance, thereby providing a very efficient overall process flow in replacement gate approaches. In other embodiments, the removal of the semiconductor material in the resistive structures may be prevented by providing a mask in accordance with conventional process strategies, wherein, prior to after replacing the semiconductor material in the gate electrode structures, the corresponding implantation process for selectively increasing the sheet resistance of the metal-containing cap material may be performed, as described above.

Consequently, non-FET devices, in particular high precision resistors, may be formed on the basis of a semiconductor material, such as polysilicon and the like, while, at the same time, gate electrode structures may be provided by using a high-k dielectric material in combination with a metal-containing electrode material or cap material, the superior conductivity of which may be selectively reduced in the resistors, so that the overall resistance value is substantially determined by the semiconductor material and the corresponding dopant profile contained therein.

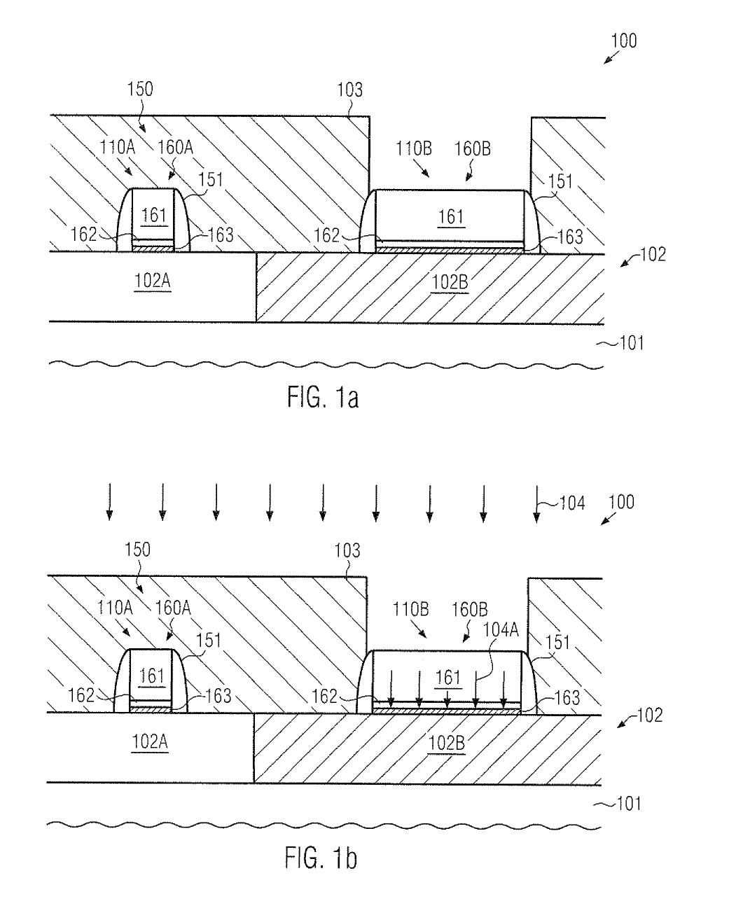

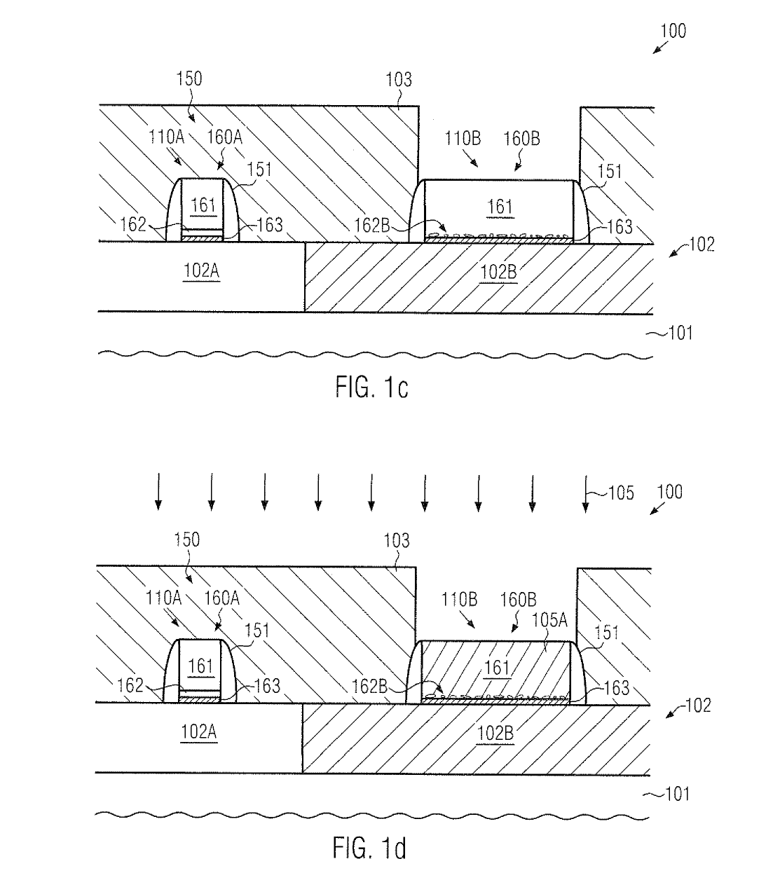

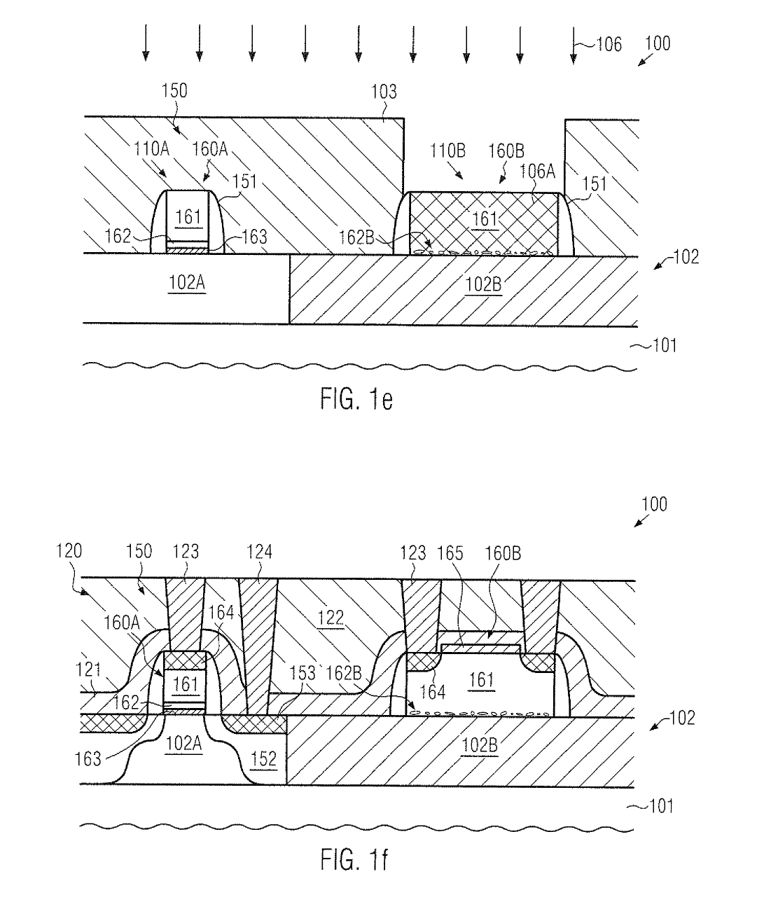

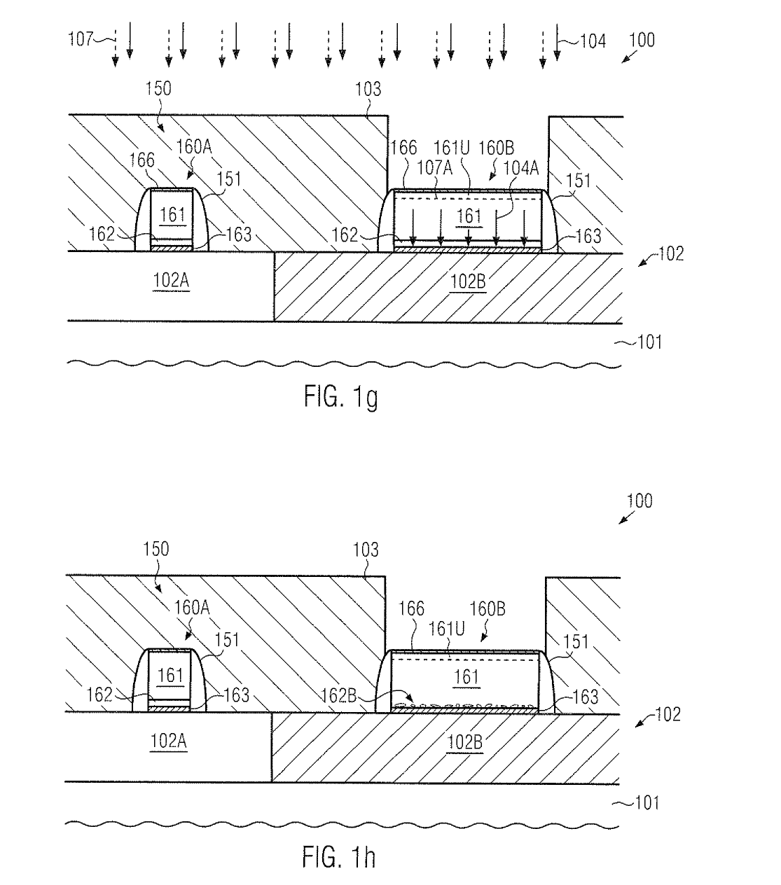

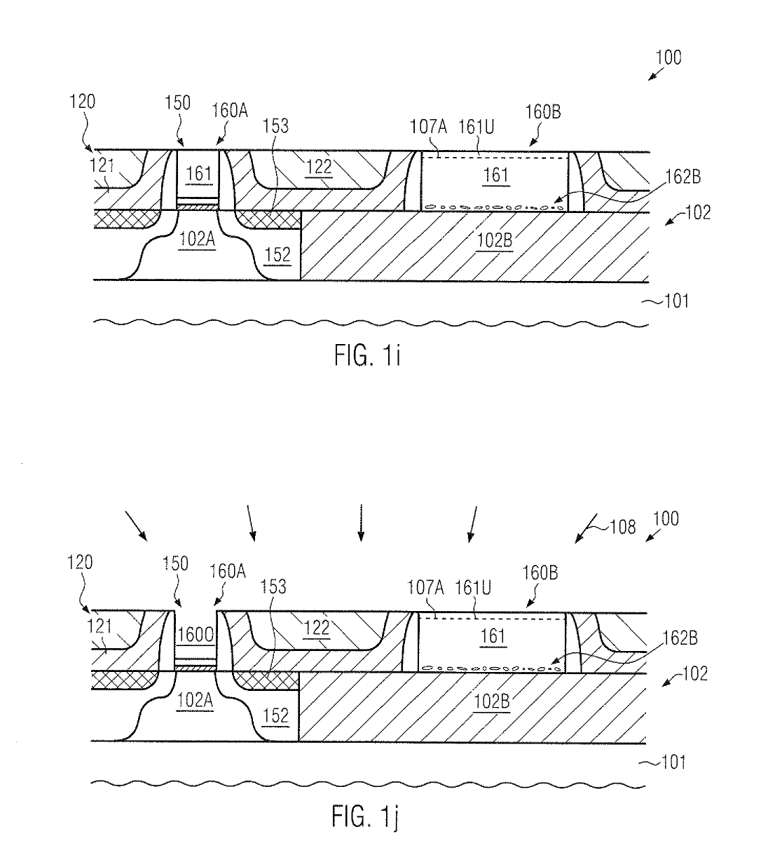

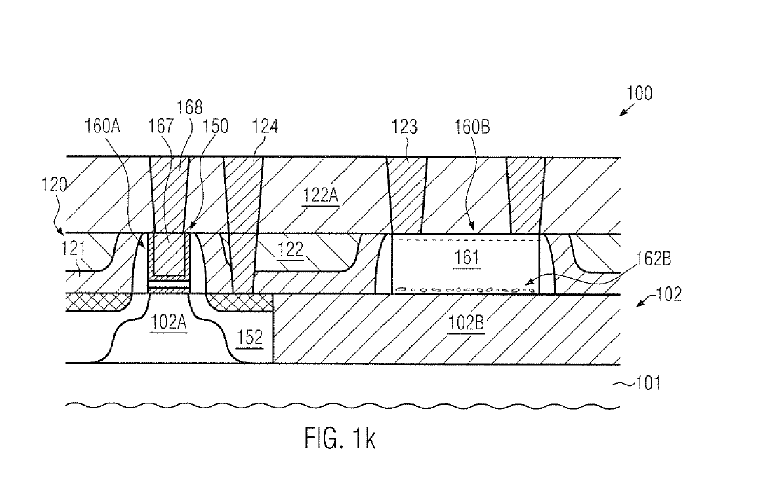

FIG. 1a schematically illustrates a cross-sectional view of a semiconductor device 100 comprising a substrate 101, above which may be formed a semiconductor layer 102. The substrate 101 and the semiconductor layer 102 may represent any appropriate carrier material and semiconductor material, respectively, for forming complex integrated circuits, wherein, as previously discussed, typically, the semiconductor layer 102 may comprise a silicon material, while the substrate 101 may represent any appropriate carrier material, such as a silicon substrate and the like. It should be appreciated, however, that the semiconductor layer 102 may comprise any appropriate material composition in order to form transistor elements and the like. The semiconductor layer 102 is to be understood as a material layer which may initially be provided as a semiconductor material and which may be subsequently divided into a plurality of active regions 102A, which are to be understood as semiconductor regions, in which appropriate PN junctions for one or more transistor elements are to be formed. The active regions 102A, only one of which is illustrated in FIG. 1a for convenience, may be separated by appropriate isolation structures, such as an isolation structure 102B. The isolation structure 102B may be provided in the form of shallow trench isolation and the like. Moreover, in the semiconductor device 100, a first device region 110A may represent one or more of the active regions 102A, in and above which transistors 150 are to be formed. On the other hand, a second device region 110B may be defined, which may represent a region in which resistive structures are to be formed. In the embodiment shown, the second device region 110B may correspond to a portion of the isolation structure 102B, thereby avoiding influence of any semiconductor material of the layer 102 on a resistor still to be formed in the second device region 110B. In the manufacturing stage shown, the device 100 may further comprise a gate electrode structure 160A of the transistor 150, which is formed above the active region 102A. Furthermore, a resistive structure 160B may be formed above the isolation structure 102B. In this manufacturing stage, the gate electrode structure 160A and the resistive structure 160B may have basically the same configuration in view of the materials provided therein, while the lateral size of these structures may differ in accordance with design requirements. For example, the gate electrode structure 160A may comprise a gate dielectric material 163, which may include a high-k dielectric material possibly in combination with a conventional dielectric material, such as a silicon dioxide based material, in order to provide a physically greater thickness while, nevertheless, preserving a desired high capacitive coupling as previously discussed. Moreover, a metal-containing cap material 162 may be formed above the gate dielectric material 163 and may be comprised of any appropriate conductive material, such as titanium nitride and the like. It should be appreciated that an additional metal species may be provided in or above the gate dielectric material 163 in order to adjust a work function of the gate electrode structure 160A. For instance, lanthanum, aluminum and the like may be provided as a distinct material layer or corresponding metal species may be incorporated in the dielectric material 163, depending on the overall process strategy. Moreover, a semiconductor material 161, which in some illustrative embodiments may represent, in combination with the cap material 162, an electrode material of the gate electrode structure 160A, may be provided, while, in other cases, as will be explained later on in more detail, the semiconductor material 161 may represent a placeholder material when applying a replacement gate approach. Furthermore, a sidewall spacer structure 151 may be provided on sidewalls of the gate electrode structure 160A. As discussed above, a length of the gate electrode structure 160A, i.e., in FIG. 1a, the horizontal extension of the materials 162 and 161, may be 40 nm and less in sophisticated applications.

Similarly, the resistive structure 160B may comprise the dielectric material 163 and the metal-containing cap layer 162 followed by the semiconductor material 161. Moreover, the spacer structure 151 may also be provided on sidewalls of the structure 160B. It should be appreciated that the resistive structure 160B may have any appropriate lateral dimension, for instance a length, i.e., in FIG. 1a, the horizontal extension of the material 161, in combination with an appropriate width in order to provide the desired resistance value of the structure 160B, while, however, the influence of the conductive cap layer 162 may be reduced, as will be explained later on in more detail.

The semiconductor material 161 may be provided in the form of a silicon material, which, in the manufacturing stage shown, may be provided in an amorphous state or in a polycrystalline state, depending on the previous process strategy. Furthermore, an implantation mask 103 may be formed above the semiconductor layer 102 so as to cover the active region 102A and the gate electrode structure 160A, while exposing at least the material 161 of the structure 160B. The implantation mask 103 may be provided in the form of a resist material having an appropriate thickness so as to avoid undue penetration of the material 161 in the gate electrode structure 160A during the further processing of the device 100.

The semiconductor device 100 as illustrated in FIG. 1a may be formed on the basis of the following process techniques. The active region 102A may be formed in the first device region 110A on the basis of well-established process techniques for providing appropriate isolation structures and for performing an appropriate implantation sequence for incorporating a desired well dopant species and other dopant species for adjusting the electronic characteristics of the active region 102A. Concurrently with any isolation structures for laterally delineating the active region 102A, the isolation structure 102B may be formed in the second device region 110B. It should be appreciated that the isolation structure 102B may not be necessarily positioned adjacent to the active region 102A, depending on the lateral positional relationship between the first and second device regions 110A, 110B. Next, a material layer stack may be deposited, for instance comprising the materials 163 and 162, which may be accomplished by any appropriate deposition techniques, possibly in combination with oxidation processes and the like. In some approaches, any materials for adjusting the work function of the gate electrode structure 160A may also be deposited and may be used as a diffusion layer for incorporating the species in the dielectric material 163. In other cases, the corresponding metal species may be provided as a distinct material layer, followed by a dielectric cap layer 162, which may reliably confine the sensitive underlying materials. Next, the semiconductor material 161 may be formed, for instance by low-pressure chemical vapor deposition (CVD) techniques and the like. Depending on the desired specific resistivity of the material 161, silicon/germanium materials may also be applied, wherein a corresponding ratio of silicon and germanium may be adjusted so as to obtain the desired electronic characteristics. In some illustrative embodiments, the material 161 may be provided in the form of an amorphous silicon material, while, in other cases, at least a part of the material 161 may be deposited as a polysilicon material. It should be appreciated that any further materials, such as dielectric cap layers, hard mask materials and the like, may also be provided in accordance with process strategies for patterning the gate electrode structure 160A and the structure 160B.

Thereafter, a complex lithography process in combination with an etch sequence may be performed so as to obtain the gate electrode structure 160A and the resistive structure 160B with the desired lateral dimensions in accordance with the design rules. Thereafter, further dopant species may be incorporated into the active region 102A in accordance with device requirements, for instance for forming drain and source extension regions (not shown) and the like. Next, the spacer structure 151 may be formed in accordance with well-established process techniques. Thereafter, further dopant species may be incorporated into the active region 102A so as to form drain and source regions (not shown), while, in other embodiments, as illustrated in FIG. 1a, corresponding processes may be performed in a later manufacturing stage. Next, the implantation mask 103 may be formed by well-established lithography techniques.

FIG. 1b schematically illustrates the semiconductor device 100 when exposed to an ion bombardment 104, in which a heavy implantation species, such as xenon, germanium, argon and the like, may be incorporated into the conductive cap layer 162 in the resistive structure 160B so as to significantly modify the structure of this material in order to increase the sheet resistance of the layer 162. That is, upon incorporating the implantation species 104A, the layer 162 may be significantly damaged, thereby efficiently interrupting the previously continuously conductive layer 162 so that the sheet resistance may be increased and may, thus, be higher compared to the specific resistivity of the semiconductor material 161, in particular, after forming a polycrystalline material. The implantation process 104 may be performed on the basis of appropriately selected process parameters, such as dose and energy, which may be readily determined by using simulation and/or experiments, for instance by determining the increase of the sheet resistance of a material layer having a similar or the same composition compared to the layer 162 for various process conditions. For example, xenon may frequently be used for amorphizing silicon material, for instance in active regions of the device 100, so as to provide superior conditions for incorporating dopant species for drain and source regions. Consequently, similar process conditions may be selected as a starting point for obtaining appropriate process parameters for incorporating the implantation species 104A, which may, thus, result in the desired increase of the sheet resistance of the material 162. Furthermore, the ion blocking effect of the implantation mask 103 may be appropriately selected such that incorporation of the implantation species 104A into the gate electrode structure 160A, at least into the material 162, may be reliably prevented, thereby preserving the previously established electronic characteristics of the gate electrode structure 160A. If required, an additional hard mask material may be selectively formed above the first device region 110A if the ion blocking efficiency of the implantation mask 103 is considered inappropriate.

FIG. 1c schematically illustrates the semiconductor device 100 in a state in which a material layer 162B has been formed during the previous implantation process 104 (FIG. 1b), which may, thus, include species of the conductive cap material 162 and, depending on the implantation dose used, also species of the layer 163, which may also be damaged in a more or less pronounced degree. Consequently, the sheet resistance of the material layer 162B may be significantly greater compared to the sheet resistance of the material 162, thereby preventing a “short circuiting” of the semiconductor material 161 and providing an overall increased resistivity for the resistive structure 160B, as may be required for forming the resistors having the desired design dimensions. On the other hand, the integrity of the gate electrode structure 160A has been preserved by the implantation mask 103.

It should be appreciated that, in some illustrative embodiments, providing the damaged material layer 162B may be accomplished at any other appropriate manufacturing stage, for instance, after depositing the semiconductor material 161 prior to actually patterning the structures 160A, 160B, while, in other cases, the material layer 162B may be formed after forming drain and source regions in the active region 102A prior to performing corresponding anneal processes for dopant activation and re-crystallization, if a polycrystalline material is to be provided in the resistive structure 160B.

FIG. 1d schematically illustrates the semiconductor device 100 according to illustrative embodiments in which an additional implantation process 105 may be performed so as to incorporate a diffusion reducing species 105A, such as carbon and the like. In the embodiment shown, the implantation process 105 may be performed by using the implantation mask 103, thereby avoiding any additional lithography processes. The diffusion reducing species 105A may be incorporated into the material 161 so as to suppress pronounced diffusion of species of the material layer 162B, thereby efficiently suppressing the reconfiguration of a continuous conductive material layer and hence preserving the high sheet resistivity of the material layer 162B during any further high temperature processes, which may be desirable in view of forming a polycrystalline material on the basis of the semiconductor material 161. The implantation process 105 may be performed on the basis of process parameters which may be established by experiments, in which appropriate concentration values and dopant distribution profiles may be determined so as to obtain the desired diffusion reducing effect. For example, process parameters, such as implantation energy, may be selected such that the species 105A may be distributed within the entire material 161, wherein appropriate dose values for the process 105 may be readily established on the basis of experiments and the like. Hence, the process parameters of the process 105 may be readily adapted to the specific conditions and configuration of the resistive structure 160B.

FIG. 1e schematically illustrates the semiconductor device 100 according to illustrative embodiments in which a further implantation process 106 may be performed so as to incorporate a dopant species 106A into the material 161. According to these embodiments, the specific resistivity of the semiconductor material 161 may be specifically adjusted on the basis of the implantation process 106, if the initial state of the material 161 may be considered inappropriate for obtaining the desired resistance value of the structure 160B. For example, upon forming the gate electrode structure 160A, an appropriate dopant concentration may have been established in the material 161 so as to comply with the requirements for obtaining a highly conductive electrode material for the structure 160A, while these requirements may not be appropriate for the resistive structure 160B. In this case, the dopant species 106A may provide the desired resistivity of the material 161 of the structure 160B. Furthermore, as illustrated, in some embodiments, the implantation process 106 may be performed on the basis of the implantation mask 103, thereby avoiding any additional lithography processes. It should be appreciated that appropriate process parameters for the implantation process 106 may be readily established on the basis of well-established simulation calculations, experiments and the like. Furthermore, since a thickness of the mask 103 has been selected so as to avoid incorporation of the implantation species in the gate electrode structure 160A upon forming the material layer 162B in the resistive structure 160B, the mask 103 may also provide sufficient ion blocking efficiency so as to reliably avoid penetration of the gate electrode structure 160A by the implantation species 106A.

FIG. 1f schematically illustrates the semiconductor device 100 in a further advanced manufacturing stage. As illustrated, the transistor 150 may comprise drain and source regions 152 in combination with metal silicide regions 153. Moreover, a metal silicide region 164 may be formed in the semiconductor material 161 of the gate electrode structure 160A. Thus, the gate electrode structure 160A may represent a high-k dielectric metal gate structure comprising the high-k dielectric material in the layer 163, while the materials 162, 161 and 164 may act as efficient electrode materials. Similarly, the resistive structure 160B may comprise the semiconductor material 161 and metal silicide regions 164, the lateral dimensions of which may be defined by an additional silicide blocking layer 165, for instance comprised of silicon nitride, silicon dioxide and the like. Thus, the resistive structure 160B or resistor may have a length that may be substantially determined by the layer 165, while the metal silicide regions 164 may represent corresponding contact areas of the resistor 160B. It should be appreciated that the remaining semiconductor material 161 may have a polycrystalline state due to the preceding processing of the semiconductor device 100.

Furthermore, the semiconductor device 100 may comprise a contact level 120, which may be understood as an appropriate interlayer dielectric material, which may comprise two or more different material layers, such as layers 122, 121, in which contact elements 123 and 124 may be provided. For example, the dielectric layer 122 may represent a silicon nitride material and the like, possibly having a high internal stress level, when a corresponding strain is to be induced in the active region 102A in order to enhance performance of the transistor 150. The dielectric layer 121 may be provided in the form of silicon dioxide and the like, depending on the overall device requirements. Furthermore, the contact level 120 may comprise contact elements 123, which may connect to portions of the metal silicide regions 164 in the gate electrode structure 160A and in the resistor 160B. Contact elements 124 may in turn connect to the active region 102A, i.e., to one or more of the metal silicide regions 153 formed therein.

The semiconductor device 100 as illustrated in FIG. 1f may be formed on the basis of the following processes. Prior to or after forming the material layer 162B having the increased sheet resistance in the resistor 160B, as described above, the drain and source regions 152 may be formed by incorporating appropriate dopant species on the basis of appropriate implantation process techniques. After forming the material layer 162, any anneal processes may be performed so as to activate the dopants in the drain and source regions 152 and re-crystallize implantation-induced damage. Furthermore, during the anneal processes, the material 161 may also be transformed into a polycrystalline state, thereby also compensating for any implantation-induced damage in the material 161 of the resistor 160B, which may have been caused upon forming the material 162B. Thereafter, the metal silicide regions 153 and 164 may be formed on the basis of any appropriate silicidation techniques, wherein the silicide-blocking layer 165 may define the lateral position and size of the regions 164 in the resistor 160B. The layer 165 may be formed at any appropriate process phase in accordance with well-established techniques. Thereafter, the materials 122 and 121 may be deposited and planarized, followed by a patterning regime for forming openings, which may be subsequently filled with an appropriate conductive material, such as tungsten, aluminum, copper and the like, so as to provide the contact elements 123 and 124. Thereafter, the processing may be continued by forming a metallization system (not shown) above the device level 120. Consequently, the resistor 160B may be provided in accordance with well-established design criteria and materials, such as polysilicon and the like, without requiring significant redesigns, since the initial low sheet resistance of a metal-containing cap material may be efficiently increased.

With reference to FIGS. 1g-1k, further illustrative embodiments will now be described in which a replacement gate approach may be applied for forming sophisticated high-k metal gate electrode structures.

FIG. 1g schematically illustrates the semiconductor device 100 according to illustrative embodiments in which the implantation process 104 may be performed on the basis of the implantation mask 103 at any appropriate manufacturing stage in order to incorporate the heavy implantation species 104A at least into the layer 162, so as to obtain the increased sheet resistance, as previously discussed. In the embodiment shown, the gate electrode structure 160A and the resistive structure 160B may additionally have formed on the semiconductor material 161 a dielectric cap material 166, such a silicon nitride, silicon dioxide and the like, which may be used for avoiding silicidation of the material 161 in the gate electrode structure 160A during the further processing of the device 100. In one illustrative embodiment, in addition to the implantation process 104, a further implantation process 107 may be performed so as to incorporate an implantation species 107A at an upper portion 161U of the semiconductor material 161. The implantation species 107A may result in a significantly increased etch resistivity of at least the upper portion 161U compared to the material 161 in the gate electrode structure in view of an etch process to be performed in a later stage in order to selectively remove the material 161 from the gate electrode structure 160A. For example, the implantation process 107 may be performed on the basis of xenon, which may result in a significant modification of the etch behavior of the material 161 in the portion 161U. In the embodiment shown, the implantation process 107 may also be performed by using the implantation mask 103, thereby avoiding any further lithography processes.

FIG. 1h schematically illustrates the semiconductor device 100 with the material layer 162B having the increased sheet resistance, as previously discussed, while also the portion 161U having the increased etch resistivity may be provided. Thereafter, the processing may be continued by performing other implantation processes, if required, for instance for incorporating a diffusion reducing implantation species, such as carbon and the like. Moreover, an additional dopant species may be incorporated, if required, as is also previously discussed. For this purpose, the implantation mask 103 may be used, as described above.

In other illustrative embodiments, the basic configuration of the semiconductor material 161 may have been adjusted in view of complying with the requirements of the resistive structure 160B, for instance in view of incorporating a diffusion reducing species in an earlier manufacturing stage, i.e., upon depositing the material 161, and/or in view of incorporating an appropriate dopant concentration, for instance upon depositing the material 161, since the material 161 may be removed from the gate electrode structure 160A in a later manufacturing stage. Consequently, any further treatments of the material 161 in the resistive structure 160B may not be necessary. Hence, the processing may be continued by removing the implantation mask 103.

FIG. 1i schematically illustrates the semiconductor device 100 in a further advanced manufacturing stage. As illustrated, the drain and source regions 152 and the metal silicide regions 153 are provided in the transistor 150, which may be accomplished on the basis of any appropriate process strategy. That is, the drain and source regions 152 may be formed prior to or after forming the material layer 162B having the increased sheet resistance, as is also previously discussed, and any anneal processes may be performed so as to activate dopants and re-crystallize implantation-induced damage. It should be appreciated that the material 161 in the resistor 160B may comprise a diffusion reducing species, such as carbon, which may have been incorporated previously, for instance, by implantation, deposition and the like. Thus, the material 161 may be transformed into a polycrystalline state, as may be desirable for the resistor 160B. On the other hand, forming a metal silicide may be suppressed by the dielectric cap material 166 (FIG. 1h). Thereafter, the portion of the contact level 120 may be formed, for instance by depositing the layers 121 and 122 and planarizing the same. During a further material removal process, for instance a polishing process, the material 161 in the gate electrode structure 160A and in the resistor 160B may be exposed, in accordance with any appropriate replacement gate approach.

FIG. 1j schematically illustrates the semiconductor device 100 when exposed to an etch ambient 108, in which the material 161 (FIG. 1i) of the gate electrode structure 160A may be removed selectively with respect to the surrounding dielectric materials and also selectively with respect to the upper portion 161U having the increased etch resistivity, as discussed above. Consequently, the etch process 108 may be performed as a non-masked etch process so as to form an opening 160O in the gate electrode structure 160A as required for forming therein any appropriate work function adjusting metal species and a metal electrode material. The etch process 108 may be performed on the basis of any selective etch recipe, such as using TMAH (tetramethyl ammonium hydroxide) and the like.

FIG. 1k schematically illustrates the semiconductor device 100 in a further advanced manufacturing stage. As illustrated, the gate electrode structure 160A may comprise a work function adjusting metal species in the form of an appropriate metal layer 168, such as a lanthanum material, aluminum and the like. Moreover, an electrode metal 167 may be provided, for instance in the form of aluminum and the like. On the other hand, the resistor 160B may comprise the semiconductor material 161 in combination with the material layer 162B having the increased sheet resistance. Furthermore, the contact level 120 may comprise an additional dielectric layer 122A, in which the contact elements 123, 124 may be formed so as to connect to the gate electrode structure 160A and to the resistor 160B, wherein a corresponding increased contact resistivity due to the missing metal silicide material may be readily taken into account when designing the resistor 160B and/or adjusting the specific resistivity of the material 161.

The semiconductor device 100 may be formed on the basis of any well-established replacement gate approaches for providing the materials 168 and 167, followed by the deposition of the material 122A and the patterning of the contact level 120, so as to form contact openings and fill the same with an appropriate conductive material to obtain the contact elements 123 and 124, as is also similarly described above.

As a result, the present disclosure provides semiconductor devices and manufacturing techniques in which resistive structures may be formed on the basis of a semiconductor material, while significantly reducing an influence of a conductive cap material that may be provided in high-k metal gate electrode structures of field effect transistors. To this end, the sheet resistance of the cap material may be increased by performing an implantation process, wherein, if required, a reconfiguration of the cap material may be prevented by incorporating a diffusion reducing species, such as carbon. In this manner, a desired polycrystalline state of the semiconductor material may be established by performing high temperature processes after performing the implantation process for increasing the sheet resistance. In other illustrative embodiments, the increasing of the sheet resistance may be accomplished after performing any high temperature processes if a corresponding damaging of a polycrystalline semiconductor material in the resistive structure may be desired.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a transistor comprising a gate electrode structure, said gate electrode structure comprising a high-k gate dielectric material and a metal-containing electrode material formed above said high-k gate dielectric material; and
a resistor comprising a semiconductor material formed above a material layer comprising species of said high-k dielectric material and of said metal-containing electrode material, said material layer having a sheet resistance that is higher than a sheet resistance of said metal-containing electrode material of said gate electrode structure.

2. The semiconductor device of claim 1, wherein said gate electrode structure further comprises a silicon-containing semiconductor electrode material formed above said metal-containing electrode material and wherein said gate electrode structure further comprises a metal silicide formed in a portion of said silicon-containing semiconductor material.

3. The semiconductor device of claim 2, wherein said resistor comprises a metal silicide material formed in a portion of said semiconductor material.

4. The semiconductor device of claim 1, wherein said resistor is formed above an isolation structure.

5. The semiconductor device of claim 1, wherein said resistor further comprises a heavy implantation species in said semiconductor material, wherein a concentration maximum of said heavy implantation species is located around said material layer.

6. The semiconductor device of claim 5, wherein said heavy implantation species comprises xenon.

7. The semiconductor device of claim 1, wherein said resistor further comprises a diffusion reducing species distributed in said semiconductor material.

8. The semiconductor device of claim 7, wherein said diffusion reducing species comprises carbon.

9. The semiconductor device of claim 1, wherein said gate electrode structure further comprises an electrode metal formed above said metal-containing electrode material.

10. The semiconductor device of claim 9, wherein said semiconductor material of said resistor comprises an upper portion and a lower portion, wherein said upper portion has incorporated therein a species imparting an increased etch resistivity to said upper portion compared to said lower portion.

11. A method of forming a resistive structure of a semiconductor device, the method comprising:
forming a gate electrode structure of a transistor above a first device region and a resistor structure above a second device region of said semiconductor device, said gate electrode structure and said resistor structure comprising a high-k dielectric material, a metal-containing cap layer and a semiconductor material; and
increasing a sheet resistance of said metal-containing cap layer selectively in said resistor structure.

12. The method of claim 11, further comprising forming a metal silicide in a portion of the semiconductor material of said gate electrode structure and in a portion of the semiconductor material of said resistor structure.

13. The method of claim 11, further comprising replacing said semiconductor material selectively in said gate electrode structure with a metal electrode material, while substantially preserving said semiconductor material in said resistor structure.

14. The method of claim 11, wherein increasing the sheet resistance of said metal-containing cap layer selectively in said resistor structure comprises implanting a heavy species into said metal-containing cap layer so as to interrupt the metal-containing cap layer.

15. The method of claim 11, further comprising incorporating a diffusion reducing species into said semiconductor material of said resistor structure so as to suppress reconfiguration of said metal-containing cap layer.

16. The method of claim 11, further comprising incorporating a dopant species into the semiconductor material of said resistor structure so as to adjust a specific resistivity of said semiconductor material.

17. The method of claim 12, wherein replacing said semiconductor material selectively in said gate electrode structure with a metal electrode material comprises selectively incorporating an etch rate reducing species selectively into said semiconductor material of said resistor structure and performing a non-masked etch process.

18. A method, comprising:
forming a resistive structure above an isolation structure of a semiconductor device, said resistive structure comprising a semiconductor material formed above a high-k dielectric material and a metal-containing cap layer; and
increasing a sheet resistance of said metal-containing cap layer by implanting a heavy species into said metal-containing cap layer.

19. The method of claim 18, further comprising implanting a diffusion reducing species into said semiconductor material.

20. The method of claim 18, further comprising implanting a dopant species into said semiconductor material so as to adjust a specific resistivity of said semiconductor material.
